(19) United States
(12) Patent Application Publication
(10) Pub. No.: US 2004/0087081 A1
(43) Pub. Date: May 6, 2004

(54) Capacitor fabrication methods and capacitor structures including niobium oxide

(76) Inventors: Bradley J. Aitchison, Eugene, OR (US); Arto Pakkala, Siuntio (FI); Pekka Kuosmanen, Espoo (FI); Kari Harkonen, Kauniainen (FI)

Correspondence Address: STOEL RIVES LLP, 900 SW FIFTH AVENUE, SUITE 2600, PORTLAND, OR, 97204, US

(21) Appl. No.: 10/611,797

(22) Filed: Jun. 30, 2003

Related U.S. Application Data
(60) Provisional application No. 60/423,114, filed on Nov. 1, 2002.

(51) Int. Cl. H01L 21/8242

(52) U.S. Cl. 438/240

(57) ABSTRACT

A dielectric structure formed on a substrate using a thin film deposition technique such as atomic layer deposition (ALD) includes at least one layer of current leakage inhibiting dielectric material, such as Al₂O₃, HfO₂, or ZrO₂, for example, in combination with niobium oxide (Nb₂O₅). The Nb₂O₅ is either incorporated into the dielectric structure as a dopant in a layer of the current leakage inhibiting material or as one or more separate layers in addition to the layer or layers of current leakage inhibiting material. The dielectric structure may be used in miniature capacitors for integrated circuit devices such as DRAM devices, for example. In some embodiments, one or more capacitor electrodes are formed around the dielectric structure in the same ALD processing system. One or more of the electrodes may comprise a transition metal nitride, a noble metal, or a noble metal alloy.

### RELATED APPLICATION

This application claims the benefit under 35 U.S.C. § 119(e) of U.S. Provisional Patent Application No. 60/423,114, filed Nov. 1, 2002, which is incorporated herein by reference.

### FIELD OF THE INVENTION

The present invention relates to the manufacture of integrated circuit devices using thin film deposition methods and, in particular, to dielectric structures created by thin film deposition methods and to capacitors including such structures that are especially useful in computer memory circuits.

### BACKGROUND OF THE INVENTION

The industry trend for miniaturization of dynamic random access memory (DRAM) chips requires progressively smaller memory cells in the DRAM chip. Miniaturization has the effect of decreasing the capacitance of the capacitors used in each memory cell. Using current technology, there is a minimum capacitance per cell that is required for reliable memory operation. If the capacitance becomes too small, electrical noise can cause memory errors. To avoid memory errors, steps must be taken to boost the capacitance of some miniature capacitors. One known way to increase the capacitance per cell has been to decrease the thickness of the dielectrics commonly used, such as SiO₂, Si₃N₄ and mixtures thereof. However if the dielectric layer is too thin, the current leakage can be unacceptably high. The semiconductor industry is currently implementing a new material, Al₂O₃, in place of SiO₂ or Si₃N₄. Al₂O₃ has a higher dielectric constant than either SiO₂ or Si₃N₄ and very good leakage characteristics, however the increase in capacitance per cell achieved by Al₂O₃ is likely to be useful for only about one technology generation. The present inventors have recognized a need for a miniature capacitor structure with increased capacitance that does not suffer from excess current leakage and which is useful for very small DRAM devices.

Capacitors are common devices used in electronics, such as integrated circuits, and particularly semiconductor-based technologies. Two common capacitor structures include metal-insulator-metal (MIM) capacitors and metal-insulator-semiconductor (MIS) capacitors. One important factor to consider when selecting a capacitor structure may be the capacitance per unit area. MIS capacitors may be advantageous since a first electrode as the semiconductor may be formed of hemispherical grain (HSG) polysilicon that exhibits a higher surface area in a given region compared to a planar surface of amorphous silicon. The higher surface area of HSG polysilicon provides more capacitance per unit area of the chip than a capacitor of the same size with electrodes having planar surfaces. ALD, with its almost perfect step coverage is an ideal means of depositing uniform coatings on high surface area devices.

A DRAM cell typically comprises a charge storage capacitor (or cell capacitor) coupled to an access device such as a Metal-Oxide-Semiconductor Field Effect Transistor (MOSFET). The MOSFET functions to apply or remove charge on the capacitor, thus affecting a logical state defined by the stored charge. The amount of charge stored on the capacitor is determined by the capacitance C=∈∈ₒA/d, where ∈ is the dielectric constant of the capacitor dielectric, ∈ₒ is the vacuum permittivity, A is the electrode (or storage node) area, and d is the interelectrode spacing. The conditions of DRAM operation such as operating voltage, leakage rate, and refresh rate, will in general mandate that a certain minimum charge be stored by the capacitor.

In the continuing trend to higher memory capacity, the packing density of storage cells must increase, yet each cell must maintain required capacitance levels. Maintaining capacitance levels while increasing packing densities are both crucial demands of DRAM fabrication technologies if future generations of expanded memory array devices are to be successfully manufactured. In the trend to higher memory capacity, the packing density of cell capacitors has increased at the expense of available cell area. For example, the area allowed for a single cell in a 64-Mbit DRAM is only about 1.4 μm². In such small areas, it is difficult to provide sufficient capacitance using conventional stacked capacitor structures. Yet, design and operational parameters determine the minimum charge required for reliable operation of the memory cell despite decreasing cell area.

As DRAM density has increased to 1 MEG (megabit/cm²) and beyond, thin film capacitors, such as stacked capacitors, trenched capacitors, or combinations thereof, have evolved in attempts to meet minimum space requirements. Many of these designs have become elaborate and difficult to fabricate consistently as well as efficiently. Furthermore, the recent generations of DRAMs (4 MEG and 16 MEG, for example) have pushed thin film capacitor technology to the limits of conventional processing capability. Thus, the present inventors have recognized the desirability for thin film dielectric materials that possess a dielectric constant significantly greater (>2-4×) than the conventional dielectrics used today, such as silicon oxides or nitrides.

### SUMMARY OF THE INVENTION

A capacitor fabrication method includes forming a dielectric structure over a first capacitor electrode and forming a second capacitor electrode over the capacitor dielectric structure. The dielectric structure includes a layer of dielectric material that has desirable current leakage inhibiting properties, such as Al₂O₃, HfO₂, or ZrO₂, for example (hereinafter “low leakage material”). Niobium oxide (Nb₂O₅), which has a high dielectric constant but also high current leakage properties, is incorporated into the dielectric structure as a dopant in the layer of low leakage material or as a separate layer in addition to the layer of low leakage material, for example as in the bi-layer structure Al₂O₃/Nb₂O₅. The layering may be continued to form a nanolaminate with from 3 to 100 layers, or more, including one or more layers of Al₂O₃ or another low leakage material and one or more layers of Nb₂O₅. By replacing a portion of the low leakage material of a conventional Al₂O₃ capacitor with a dopant of Nb₂O₅ or a layer of Nb₂O₅, the overall dielectric constant may be improved while also benefiting from the current leakage inhibiting properties of the low leakage layer, to thereby allow a higher capacitance density than previously available.

In some embodiments, an atomic layer deposition (ALD) method is used to form the dielectric structure which includes Al₂O₃ in a low leakage layer in combination with a layer of Nb₂O₅. In other embodiments, HfO₂ or ZrO₂ may be used in the low leakage layer. Still other embodiments may include mixtures of Ta₂O₅ and Nb₂O₅, which may be layered with a low leakage layer such as Al₂O₃. Another embodiment may include the utilization of ALD to form one or more electrodes of TiAlN, NbN, or a mixture thereof, preferably placed adjacent an Nb₂O₅-containing layer, to reduce leakage current. The dielectric structure and one or more of the electrodes can be formed in an ALD reaction chamber in a single processing cycle without removing the substrate from the ALD reaction chamber between layering steps.

Miniature capacitors formed in accordance with the methods described herein may be used in a variety of integrated circuit devices, such as DRAM devices, for example.

### BRIEF DESCRIPTION OF THE DRAWINGS

FIG. 1 shows a cross section of a capacitor including a two layer aluminum-niobium-oxide structure.

FIG. 2 shows a cross section of another capacitor having a three layer aluminum-niobium-oxide structure.

FIG. 3 shows a cross section of a further capacitor having a five layer aluminum-niobium-oxide nanolaminate structure.

FIG. 4A shows a cross section of an aluminum-niobium-oxide dielectric structure formed by ALD over the surface of a deep container structure.

FIG. 4B shows a cross section of a capacitor including the deep container structure and dielectric layer of FIG. 4A.

FIG. 5 shows a cross section of still another capacitor including an aluminum-niobium-oxide layer formed by ALD in a deep container structure including surface area enhancement features.

FIG. 6 is a graph illustrating performance in leakage current density of Al₂O₃ relative to aluminum-niobium-oxide over a range of capacitance densities.

FIG. 7 is a chart illustrating the effect of different electrode-to-dielectric interfaces on capacitor leakage current density, as a function of applied voltage.

### DETAILED DESCRIPTION OF PREFERRED EMBODIMENTS

Throughout the specification, reference to “one embodiment”, or “an embodiment”, or “some embodiments” means that a particular described feature, structure, or characteristic is included in at least one embodiment. Thus, appearances of the phrases “in one embodiment” or “in an embodiment” or “in some embodiments” in various places throughout this specification are not necessarily all referring to the same embodiment.

Furthermore, the described features, structures, or characteristics may be combined in any suitable manner in one or more embodiments. Those skilled in the art will recognize that the invention can be practiced without one or more of the specific details, or with other methods, components, materials, etc. In other instances, well-known structures, materials, or operations are not shown or not described in detail to avoid obscuring aspects of the embodiments.

### Thin Film Deposition Techniques

Atomic layer deposition (ALD), formerly known as atomic layer epitaxy (ALE), is a thin film deposition process that has been used to manufacture electroluminescent (EL) displays for over 20 years. See, e.g., U.S. Pat. No. 4,058,430 of Suntola et al., incorporated herein by reference. Recently the ALD technique has gained significant interest in the semiconductor processing industry. The films yielded by ALD have exceptional characteristics such as being pinhole free and possessing almost perfect step coverage. Although ALD is similar to chemical vapor deposition (CVD), it is significantly different in practice. In particular, the flows of precursors in CVD are static while in ALD they are dynamic.

To grow the films using ALD, substrates are placed in a reaction chamber that is heated to between about 200° C. and about 600° C. and pumped down to a pressure of approximately 1 Torr. Once the substrate reaches a stable temperature, a first precursor chemical vapor is directed over the substrate. Some of this vapor chemisorbs on the surface of the substrate to make a film that is one monolayer thick. For true ALD, the precursor will not attach to the chemisorbed monolayer and the layer growth process is therefore self-limiting. Next any excess of the first precursor and any volatile reaction products are removed from the reaction space by a purging step, described below. Next a second precursor chemical vapor is introduced into the reaction chamber and chemisorbs to the surface of the monolayer of the first chemisorbed precursor. The second precursor reacts with the chemisorbed monolayer of the first precursor to form a layer of a first compound. Finally, any excess of the second precursor and any volatile reaction products are removed by purging the reaction space. This completes one cycle. This procedure is repeated until the desired thickness of the film is achieved. A cycle may include more than 2 precursors, for example: first precursor, first purge, second precursor, second purge, third precursor, third purge, etc.

Films deposited by ALD may include epitaxial, polycrystalline, and amorphous layers, and others. ALD is described below as one possible manufacturing process for creating thin dielectric films and capacitors in accordance with preferred embodiments. However, suitable manufacturing methods may also include the use of other thin layer deposition processes not traditionally referred to as ALD, such as chemical vapor deposition (CVD) and others. Furthermore, while the embodiments described below involve the formation of thin dielectric films on a semiconductor wafer substrate, other embodiments may encompass other thin dielectric films and capacitors not formed on semiconductor wafer substrates, and thus not be limited to the use of semiconductor wafer substrates.

In the context of this document, the term “semiconductor substrate” or “semiconductive substrate” is defined to mean any structure comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” refers to any substrate, including, but not limited to, the semiconductive substrates described above.

As described above, ALD includes exposing a substrate to a first chemical species (a “first precursor”) to accomplish chemisorption of the first precursor onto the substrate. The first precursor is vaporized (if not normally gas phase) before exposure, typically by heating and drawing a vacuum in a container that holds a supply of the first precursor. An amount of the first precursor is then directed over the substrate, where it chemisorbs to the surface of the substrate. Theoretically, the chemisorption forms a monolayer that is uniformly one atom or molecule thick over substantially the entire exposed area of the substrate, in other words, a saturated monolayer. In practice, chemisorption might not occur on all portions of the substrate, resulting in an imperfect monolayer. Nevertheless, such an imperfect monolayer may still comprise a monolayer. In many applications, a substantially saturated monolayer may be suitable. A substantially saturated monolayer exhibits certain minimum qualities and/or properties desired in a thin film structure. In other applications, a monolayer that is not substantially saturated may be acceptable.

After exposure of the substrate to the first precursor, excess amounts of the first precursor are purged away from the substrate leaving the monolayer of the first precursor (“the first monolayer”) substantially intact. The substrate is then exposed to a second chemical species (a “second precursor”) that chemisorbs onto the first monolayer, to thereby form a second monolayer thereon. As with the first precursor, the second precursor must be vaporized before exposure, unless normally existing in gas phase. After exposure of the substrate, excess amounts of the second precursor are then purged and the steps of first precursor—purge—second precursor—purge are repeated. In some cases, adjacent monolayers may be of the same species, for example when performing so called “double pulsing” for improved thin film uniformity. Also, three or more different chemical species may be successively chemisorbed and purged during film deposition in a manner similar to the chemisorption of the first and second precursors described above.

Purging may include one or more of a variety of techniques including, but not limited to, directing a flow of purge gas over the substrate, lowering the pressure in the reaction space below the deposition pressure to reduce the concentration of non-chemisorbed precursor in the reaction space. Purging and pressure regulation typically involves a reaction chamber of an ALD machine interposed between a vacuum pump and a source of purge gas. Examples of purge gases include N₂, Ar, He, Kr, Ne, and Xe. Purging may also include contacting the substrate and/or monolayer with any substance that allows chemisorption byproducts to desorb and reduces the concentration of a contacting precursor preparatory to introducing another precursor. A suitable amount of purging can be determined with routine experimentation, as known to those skilled in the art. For example, purging time may be successively reduced until an increase in film growth rate occurs. The increase in film growth rate might be an indication of a change to a non-ALD process regime and may be used to establish a purge time limit.

ALD is traditionally performed within an often-used range of temperature and pressure and according to established purging criteria to achieve the desired formation of a thin film one monolayer at a time. Even so, ALD conditions can vary greatly depending on the particular precursors, layer composition, deposition equipment, and other factors according to criteria known by those skilled in the art. Maintaining the traditional conditions of temperature, pressure, and purging minimizes unwanted reactions that may negatively impact monolayer formation and quality of the resulting thin film. Accordingly, operating outside the traditional temperature and pressure ranges may risk formation of defective monolayers. However, doing so can significantly increase the rate of deposition.

ALD is often described as a self-limiting process, in that a finite number of reaction sites exist on a substrate to which the first precursor may form chemical bonds. The second precursor might only bond to the first precursor (and not itself) and thus may also be self-limiting. Once all of the reaction sites on a substrate are bonded with a first precursor, the first precursor will often not bond to other of the first precursor already bonded with the substrate. However, process conditions can be varied in a quasi-ALD process to promote such first precursor-to-first precursor bonding and render the process not self-limiting. Accordingly, as used herein, ALD may also encompass quasi-ALD, i.e., forming more than one monolayer at a time by stacking of a single species. The mechanism of quasi-ALD differs from CVD in that the reactions in quasi-ALD take place at the surface of the substrate, rather than in the space above the surface. Quasi-ALD may also provide faster deposition rates than traditional ALD. Quasi-ALD films have many of the same advantages over CVD films as are also provided by traditional ALD, such as conformity and pinhole-free coverage. The various aspects of the preferred embodiment described herein are, therefore, also possible with quasi-ALD processing.

The general technology of chemical vapor deposition (CVD) includes a variety of more specific processes, including, but not limited to, plasma enhanced CVD and others. CVD is commonly used to form non-selectively a complete, deposited material on a substrate. One characteristic of CVD is the simultaneous presence of multiple chemical species in the deposition chamber that react to form the deposited material. This deposition characteristic of CVD is contrasted with traditional ALD wherein intermediate purging allows a substrate to be sequentially exposed to precursors that chemisorb to the substrate or to a layer of previously deposited precursor. An ALD process regime may provide a simultaneously contacted plurality of species of a type or under conditions such that ALD chemisorption, rather than CVD reaction occurs. Instead of reacting together in the reaction space, the species chemisorb to a substrate or previously deposited species, providing a surface onto which subsequent species may next chemisorb to form a complete layer of desired material. Under most CVD conditions, deposition occurs largely independent of the composition or surface properties of an underlying substrate. By contrast, the chemisorption rate in ALD might be influenced by the composition, crystalline structure, and other properties of a substrate or chemisorbed species. Other process conditions, for example, pressure and temperature, may also influence chemisorption rate.

### Capacitor Fabrication and Dielectric Materials

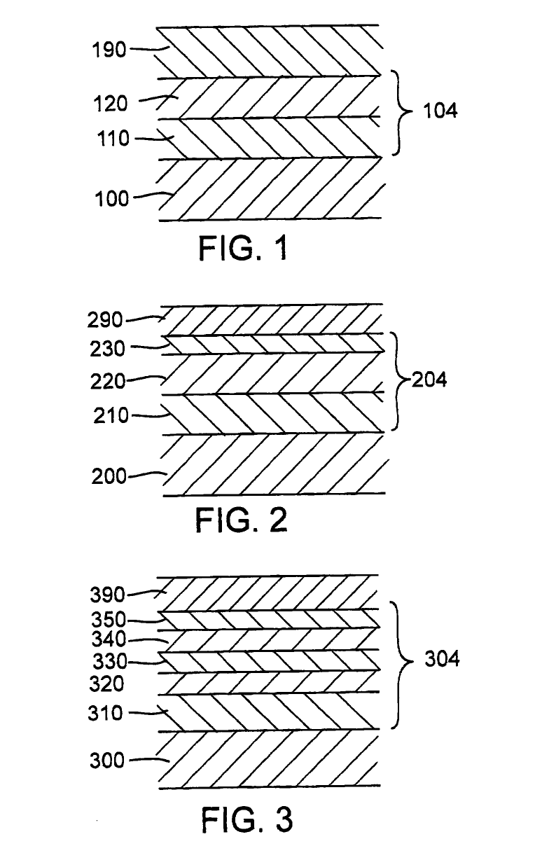

Thin film deposition techniques, including ALD, are considered useful in fabrication of capacitors. An enlarged cross section view of a first embodiment of a miniature capacitor structure formed by the ALD method is shown in FIG. 1. The miniature capacitor structure may be part of an integrated circuit device, such as a DRAM device. With reference to FIG. 1, a capacitor fabrication method includes forming a first capacitor electrode over or within a substrate 100. A capacitor dielectric structure 104 is formed by ALD over the first electrode and a second capacitor electrode 190 is formed over the dielectric structure 104. One or more of the capacitor electrodes may comprise polysilicon. Forming the first and second electrodes 100, 190 may be accomplished by methods known to those skilled in the art, including thin film deposition techniques such as ALD.

Prior to ALD processing, it may be advantageous to clean substrate 100, which may include cleaning any previously deposited layers such as the first electrode, for example. Cleaning may be accomplished by a method such as HF dip, HF vapor clean, NF₃ remote plasma or another suitable method. Such cleaning methods may be performed in keeping with the knowledge of those skilled in the art.

Dielectric structure 104 includes a layer of current leakage inhibiting material 110 (hereinafter “current leakage inhibiting layer” or “low leakage layer”), comprising, for example, Al₂O₃, HfO₂, ZrO₂, and/or another oxide material that has low current leakage properties. A typical low leakage layer having a thickness that results in a capacitance of about 20 nF/mm² may have a leakage less than 1×10⁻⁶ amps/cm², for example. Nb₂O₅ is incorporated into the dielectric structure as a dopant in the low leakage layer 110 or as a separate high capacitance density layer 120 in addition to the low leakage layer 110, for example as a bi-layer structure of Al₂O₃/Nb₂O₅ such as the structure shown in FIG. 1.

The present inventors have discovered that the leakage current of dielectric structure 104 exhibits a strong dependence on the interface between electrodes 110 and 190 and the dielectric structure 104. Accordingly, it may be advantageous with certain first electrode materials to utilize a bi-layer structure of Nb₂O₅/Al₂O₃, in which low leakage layer 110 and niobium layer 120 are deposited over the first electrode in the reverse order from that shown in FIG. 1.

The layered dielectric structure may be extended to a so-called nanolaminate structure. A nanolaminate typically can have from 3 to 100 layers, each consisting of a thin film of one or more dielectric materials. There is a practical limit to the number of layers as the leakage current will increase significantly if the layer thickness of the low leakage layer is much less than 3 nm (30 angstroms (Å)). An embodiment of a 5-layer nanolaminate dielectric structure 304 is shown in FIG. 3, including layers 310, 320, 330, 340, and 350, as follows, with thickness indicated in angstroms (Å): 32 Å Al₂O₃/6 Å Nb₂O₅/4 Å Al₂O₃/6 Å Nb₂O₅/4 Å Al₂O₃.

In another aspect, formation of high capacitance density layer 120 may include doping or mixing Nb₂O₅ with a material selected from the group including Al₂O₃, Ta₂O₅, TiO₂, HfO₂, ZrO₂ or a combination thereof. Doping or mixing can increase the capacitance density and/or decrease the leakage current of the Nb₂O₅. Doping and mixing can be performed using ALD techniques by alternating layers of Nb₂O₅ with the other material, in a desired ratio.

In another embodiment (not shown), a capacitor fabrication method includes forming a layer of a conductive interface material over the substrate. The conductive interface material may be used in combination with a separate first capacitor electrode or may serve as the first capacitor electrode. If serving as the first capacitor electrode, the conductive interface material is preferably at least 50 Å thick. A capacitor dielectric layer is formed over the conductive interface material and a second capacitor electrode is formed over the dielectric layer. The conductive interface material may be selected to improve dielectric properties and leakage current density properties through surface interface interaction with the dielectric structure.

In the various embodiments described herein, the conductive interface material (e.g., the first and/or second electrodes) may comprise titanium nitride (TiN), or other transition metal nitride materials, such as NbN, TiAlN, WN, WSiN, TaN, and TiSiN. One or more of the electrodes may, alternatively, comprise noble metals or noble metal alloys, such as Pt, Pt alloys, Ir, Ir alloys, Pd, Pd alloys, RuOₓ and IrOₓ. The electrodes may be deposited by ALD, CVD, and perhaps other methods.

In further embodiments (not shown), the conductive interface material is formed over rather than under the dielectric layer, thereby serving as the second capacitor electrode or cooperating with a separate second capacitor electrode. A corresponding capacitor fabrication method includes forming a first capacitor electrode over or within a substrate, forming a dielectric structure over the first electrode, forming a layer of a conductive interface material over the dielectric structure and, optionally, forming a second electrode over the conductive interface material. In yet another embodiment, a dielectric assembly includes a dielectric structure is sandwiched between two layers of conductive interface material. The dielectric assembly may, in turn, be sandwiched between separate first and second electrodes.

In a preferred method, deposition of the dielectric structure using ALD may occur at a temperature ranging between approximately 100° C. and approximately 600° C. and at a pressure ranging between approximately 0.1 Torr and approximately 10 Torr. This method may be used in connection with any of the embodiments described herein and may also be used to form electrode layers, cap layers, conductive interface layers, and other integrated circuit layer structures. The dielectric structure formed in accordance with the methods described herein preferably exhibits a K factor (K factor=relative dielectric=∈ᵣ) of greater than about 14 at 20° C. A K factor of greater than about 14 allows the dielectric layer to be thick enough to prevent quantum mechanical tunneling while providing the needed capacitance density.

Examples of pairs of first and second precursors used in ALD for forming dielectric structures 104 (and 204, 304, 404, and 504), include: TMA/H₂O, Nb-ethoxide/H₂O, Nb-ethoxide/H₂O₂, Nb-ethoxide/O₃, Nb-ethoxide/NO, Nb-ethoxide/O₂, NbCl₅/NH₃, and TiCl₄/NH₃ (where TMA is trimethyl aluminum and Nb-ethoxide is Nb(C₂H₅O)₅). It is conceivable that more than one of the preceding pairs may comprise the first and second precursors, but preferably only one of the pairs. The second precursor is typically an oxidizer. It is also conceivable that more than one oxidizer may be used at the same time or sequentially. Other precursor species not listed above may also be useful in forming dielectric structures 104, 204, 304, 404, and 504.

Prior art methods of forming a first electrode layer, a dielectric layer and a second electrode layer involve transferring the substrate to different processing tools for each layer, possibly including cleaning steps between each layer deposition step. In contrast, the use of ALD in accordance with the preferred embodiments described herein allows all of the capacitor parts described herein (including first and second electrodes, the dielectric structure, and any layers of conductive interface material) to be deposited in the same ALD reactor during the same pump down cycle. Avoiding substrate transfers between processing tools and depositing electrodes and dielectric layers during a single pump down cycle has cost benefits in the way of manufacturing efficiency and speed, as well as quality benefits such as fewer particles and defects.

While ALD is particularly suitable for forming the layers (110, 120, 210, 220, 310, 320, 330, 340, 350, etc.) of dielectric structures (104, 204, 304, 404, 504) and the respective first and second electrodes of the various embodiments, other thin film deposition methods, such as CVD for example, may also be suitable.

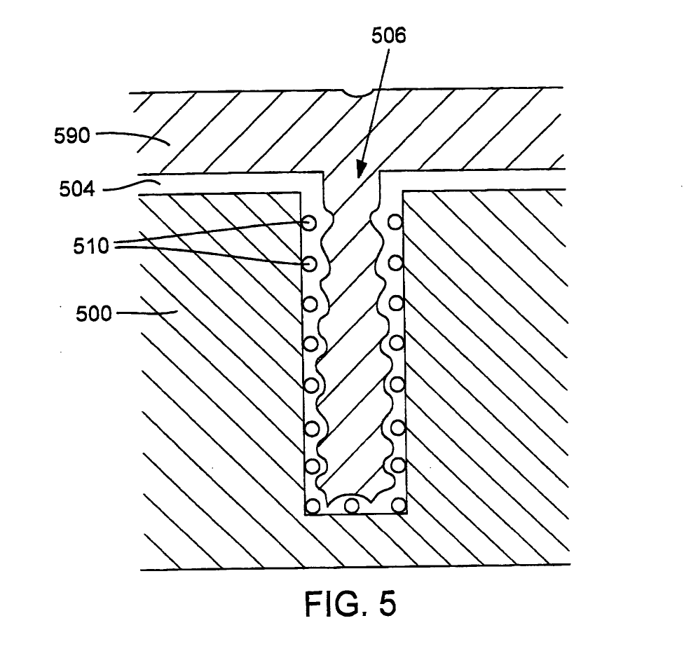

In some embodiments, a capacitor fabrication method includes forming a first capacitor electrode over a substrate where the first electrode has an inner surface area per unit area and an outer surface area per unit area that are both greater than an outer surface area per unit area of the substrate. With reference to FIG. 5, one example of obtaining the inner and outer electrode surface areas involves further forming rough polysilicon 510 (sometimes called “rugged polysilicon”) over the substrate 500 and forming the first electrode (not shown) over the rough polysilicon. The first electrode can also be comprised of the rough polysilicon 510. The rough polysilicon 510 preferably has a surface area per unit area greater than the surface area per unit area of conventionally formed polysilicon. A capacitor dielectric structure 504 may be formed over the first electrode, followed by a second capacitor electrode 590 may be formed over the dielectric structure 104, to produce a capacitor structure.

The rough polysilicon 510 may be HSG and it can also be undoped. By using rough polysilicon, for example, a first electrode may be formed having an outer surface area that is at least 30% greater the substrate outer surface area. Advantageously, the surface area enhancing material need not comprise polysilicon to accomplish the surface area enhancement. Further, it is conceivable that the first electrode can be formed over materials other than rough polysilicon that provide enhanced surface area in comparison to the substrate underlying the first electrode. The dielectric layer 504 is preferably a niobium-containing dielectric or a niobium-containing multilayer structure or nanolaminate. The second electrode 590 may be formed of the same material as the first electrode, or preferably from a different material selected from the group including doped silicon, transition metal nitrides, noble metals, noble metal alloys, and combinations thereof. Using different materials for the first and second electrodes may provide advantages due to differences in the valence and electron band alignments of the various layers of the capacitor.

To achieve significant improvements in first electrode surface area, rough polysilicon may be formed using a seed density sufficiently small to yield at least some spaced apart grains. Sufficient spacing prevents the leveling effect of subsequent capacitor layers from filling the space between grains and reducing the capacitance enhancement possible with the first electrode of increased surface area. Conventionally, HSG is formed with very closely positioned grains to optimize surface area since HSG is often doped for use as a capacitor electrode in prior art capacitors. In contrast, devices of the preferred embodiments may have significant spacing between grains, which can be tolerated because the first electrode can be formed over the polysilicon rather than within the polysilicon. The spaced grains provide increased outer surface area for the first electrode, as compared the substantially smooth surface of conventionally-formed closely packed HSG polysilicon. Also, in the preferred embodiments, the HSG may be undoped. Undoped grains of rough polysilicon may have a grain size that is smaller than doped grains, allowing a smaller electrode separation distance to be used.

FIGS. 1 to 5 show several embodiments of capacitors including aluminum-niobium-oxide (hereinafter “AlNbO”) dielectric structures.

FIG. 1 is a cross section view of a first preferred embodiment of a capacitor structure including a multilayer stack of thin films 104 forming a dielectric structure. With reference to FIG. 1, a substrate 100 is provided, which may be doped silicon or another conductive material forming the first electrode of the capacitor structure. Using the ALD technique, a low leakage dielectric layer 110 is grown on substrate 100. The low leakage dielectric layer 110 (hereinafter “first layer 110”) includes a high resistivity material such as, for example, SiO₂, Al₂O₃, HfO₂, ZrO₂, other low leakage metal oxides, and mixtures or combinations thereof. The leakage current of the first layer 110 should be less than about 1×10⁻⁶ amps/cm² at positive or negative 1.8V. If the first layer 110 is too thin the leakage current of the dielectric structure 104 of FIG. 1 will be too high. If the first layer 110 is too thick the capacitance density of dielectric structure 104 will be too low. The thickness of the low leakage layer 110 may be in the range of approximately 20 Å to approximately 50 Å, and preferably in the range of between approximately 30 Å and approximately 35 Å. Next a layer 120 of Nb₂O₅ (hereinafter “second layer 120”) is grown over the first layer 110. The second layer 120 should be thick enough to avoid quantum mechanical tunneling of electrons through the dielectric structure 104, but not so thick that it undesirably reduces the capacitance density of the dielectric structure 104. The overall thickness of dielectric structure 104 preferably exceeds approximately 49 Å to avoid quantum mechanical tunneling effects. A suitable range of thickness of second layer 120 is between about 0.3 Å and about 70 Å, depending on the thickness of first layer 110. In combination, the overall leakage current density of the assembly of the first and second layer is about 1×10⁻⁷ amps/cm² at +/−1.8V. Finally a second electrode 190 is deposited over second layer 120.

FIG. 2 is a cross section view of a second embodiment of a capacitor. The layers 200, 204, 210 and 220 of the second capacitor offer the same purpose as their 100-series counterparts of the capacitor of FIG. 1. For example, a first electrode is formed on or within a substrate 200 and first and second layers 210 and 220 comprise a multilayer stack dielectric structure 204 of a low leakage layer and an Nb₂O₅-containing high capacitance density layer. In addition, the embodiment of FIG. 2 includes a cap layer 230 to protect Nb₂O₅ of second layer 220 of dielectric structure 204. Cap layer 230 inhibits reduction of Nb₂O₅, for example, during the deposition of the second electrode 290. It is also possible to improve (i.e., decrease) leakage current density of dielectric structure 204 by tailoring the material of the cap layer 230 for cooperation with the Nb₂O₅ material of the second layer 220. The cap layer 230 should be thick enough to protect the Nb₂O₅, but not so thick as to significantly decrease the capacitance density of the dielectric structure 204 of layers 210, 220 and 230. Typically the cap layer 230 may be approximately 3 Å to 10 Å thick. Preferably the cap layer is made of a low leakage material, such as the high resistivity materials described above, for example, SiO₂, Al₂O₃, HfO₂, ZrO₂, other low leakage metal oxides, and mixtures thereof, including laminates and other combinations of low leakage materials.

FIG. 3 is a cross section view of yet another embodiment of a capacitor, including a 5-layer dielectric structure 304. The layers 300, 310 and 320 offer the same purpose as their 100-series counterparts in FIG. 1. In the capacitor of FIG. 3, multiple interfaces of differing materials decrease the leakage current density through the dielectric structure 304. Layers 320 and 340 include Nb₂O₅ while layers 330 and 350 are formed of a high resistivity low current leakage material as listed above (including mixtures, combinations, and laminates of different high resistivity materials). Each of the individual layers (320, 330, 340, and 350) may have a thickness in the range of approximately 3 Å to approximately 10 Å, for example.

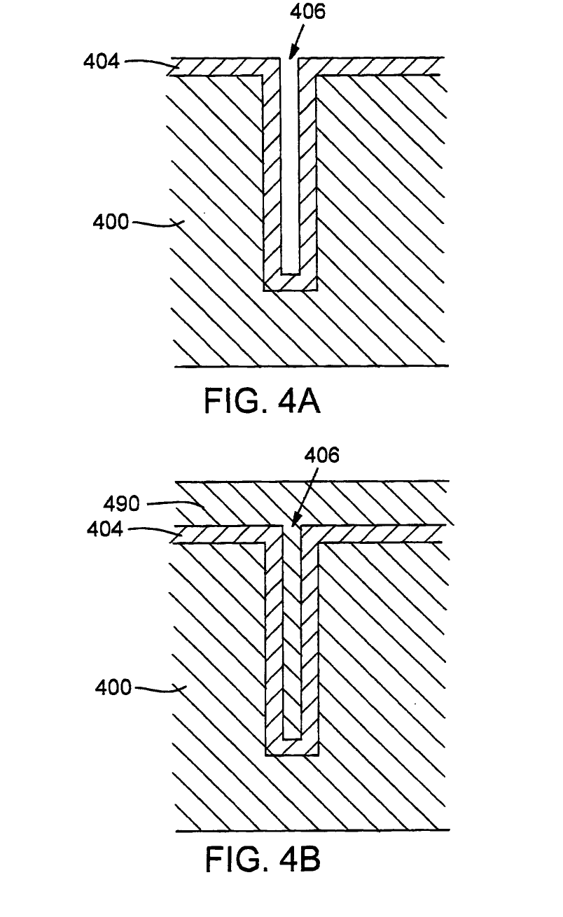

FIG. 4A is a cross section view of a substrate structure 400 of high surface area for use with the multi-layer dielectric structures (104, 204, 304) of the above-described capacitor embodiments. A via 406, trench, or other container structure is formed in the substrate 400. Thereafter, an Nb₂O₅-containing dielectric structure 404 is deposited using ALD to conformally coat the surface of the substrate 400, including the via 406.

FIG. 4B is a cross section view of a capacitor using the thin film of FIG. 4A, and further including a second electrode 490 deposited over dielectric film 404, so that the second electrode 490 fills the via 406. With reference to FIG. 4B, the substrate 400 is a silicon substrate that is doped in the region of the via 406 so that it is conductive to thereby form a first electrode of the capacitor. The dielectric film structure 404 can include niobium, for example, in the form of an Nb₂O₅-doped low leakage layer and/or a nanolaminate of the types described above with reference to FIGS. 1-3. Finally a second electrode 490 is deposited over the dielectric structure 404 to complete the capacitor of FIG. 4B.

FIG. 5 shows a similar structure as in FIG. 4B, but with surface area enhancements to increase capacitance of the device. With reference to FIG. 5, a plurality of surface enhancing silicon grains 510 (HSG) are deposited on the walls of a via 506 that is formed in a semiconductor substrate 500. The silicon grains 510 may be doped or undoped. If both the substrate 500 and the silicon grains 510 are undoped, then a conductive electrode layer (not shown) is deposited, preferably by ALD, over the silicon grains and the substrate 500. A niobium containing dielectric structure 504 is deposited over substrate 500 and silicon grains 510 (and the conductive electrode layer, if separate from substrate 500). The niobium containing dielectric structure 504 may comprise an low leakage layer doped with Nb₂O₅, or a multi-layer dielectric structure or nanolaminate including at least one low leakage layer and at least one Nb₂O₅-containing high capacitance density layer, such as the structures 104, 204, 304 described above with reference to FIGS. 1-3. A conductive second electrode layer 590 is deposited over the niobium containing film 504 and fills the via 506, to thereby complete the capacitor device.

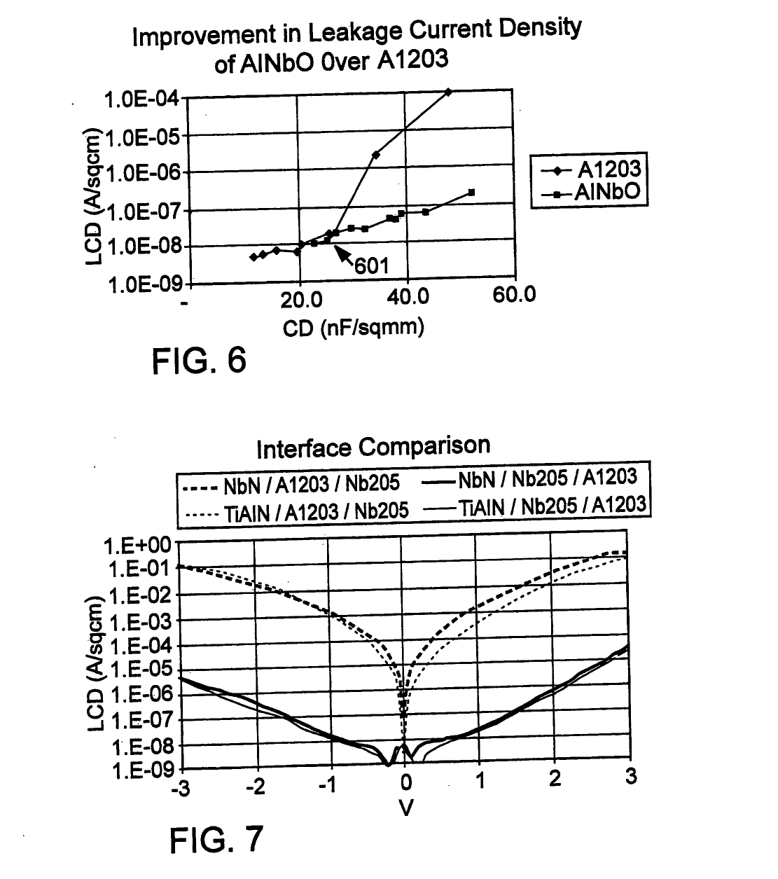

FIG. 6 is a chart illustrating performance in leakage current density of Al₂O₃ relative to AlNbO as thickness is decreased, giving rise to a corresponding increase in capacitance density (CD). Both sets of data are from films grown on Si substrates including a SiO₂ layer of native oxide that is approximately 13 Å thick. The “Al2O3” data is taken from a group of samples with Al₂O₃ thicknesses ranging from 19 Å to 74 Å. A knee 601 in the Al₂O₃ curve, at a capacitance density of approximately 25 nF/mm², corresponds to an Al₂O₃ layer having a thickness of about 36 Å. This knee 601 corresponds to what appears to be the onset of quantum mechanical tunneling, when the combined thickness of the Al₂O₃ layer and the SiO₂ layer is approximately 49 Å.

The AlNbO data in FIG. 6 is from a group of nine Al₂O₃/ Nb₂O₅ bi-layer samples of selected thicknesses of Al₂O₃ and Nb₂O₅. The Al₂O₃ thicknesses are about 14 Å, 18 Å and 22 Å while the corresponding Nb₂O₅ layer thicknesses are about 45 Å, 75 Å and 105 Å, for combined bi-layer structure thicknesses of approximately 59 Å, 93 Å, and 127 Å (two samples of each). It is noted that even the thinnest AlNbO sample is thicker than the 49 Å minimum thickness to avoid quantum mechanical tunneling.

FIG. 6 illustrates that in the absence of quantum mechanical tunneling (i.e., at thicknesses of greater than 49 Å), the leakage current densities of Al₂O₅ and AlNbO are approximately the same for similar current densities. Furthermore, both materials have leakage current densities that increase generally linearly as the capacitance density increases. However, above a capacitance density of about 25 nF/mm² the leakage current density of Al₂O₃ increases (degrades) much more sharply as thickness falls below 49 Å. In contrast, the leakage current density of AlNbO continues to increase proportionally above a corresponding capacitance density of 25 nF/mm², up to 50 nF/mm² and beyond. Thus, niobium containing dielectric structures can provide capacitance density performance in excess of 25 nF/mm² and in excess of 50 nF/mm² without unacceptable levels of leakage current density. For example, in one experiment, a niobium containing dielectric material was formed with a capacitance density of greater than 50 nF/mm² and a leakage current density of less than 1.0×10⁻⁶ amps/cm². By comparison, undoped Al₂O₃ exhibited a leakage current density of approximately 1.0×10⁻⁴ at a corresponding capacitance density of approximately 50 nF/mm², due to quantum mechanical tunneling. In another experiment, a niobium containing dielectric material was formed with a capacitance density of greater than 30 nF/mm² and a leakage current density of substantially less than 1.0×10⁻⁷ amps/cm².

FIG. 7 is a chart illustrating the effect on the leakage current density (LCD) of interfaces between the niobium containing dielectric structure and adjacent electrodes of different materials. Two equally thick AlNbO bi-layer films (Al₂O₃/Nb₂O₅) are compared in FIG. 7. One has the Al₂O₃ layer against the bottom electrode, as follows: bottom electrode/Al₂O₃/Nb₂O₅/top electrode. The other has the Nb₂O₅ layer against the bottom electrode, as follows: bottom electrode/Nb₂O₅/Al₂O₃/top electrode. Bottom electrodes made from TiAlN and NbN were tested, as indicated in the legend for FIG. 7. For testing purposes, a mercury probe was used for the top electrode of each test sample. The samples with the Nb₂O₅ layer against the bottom electrode exhibited over 4 orders of magnitude less leakage current as compared with the samples that have the Al₂O₃ layer against the bottom electrode. The significant difference in performance illustrates the influence of the interfaces on the leakage current properties of these extremely thin films and the influence of the surface for ALD growth. A further benefit of the structure with Nb₂O₅ adjacent a layer of NbN is that if the film is annealed and some or all of the NbN oxidizes (so that all or part of the NbN layer is converted to Nb₂O₅), it merely supplements the Nb₂O₅ layer. Because Nb₂O₅ has a high dielectric constant, the capacitance of the dielectric structure will not decrease significantly as a result of such a conversion during annealing.

Those having skill in the art will recognize that many changes may be made to the details of the above-described embodiments without departing from the underlying principles of the invention. The scope of the present invention should, therefore, be determined only by the following claims.

1. A miniature capacitor, comprising:
a first electrode;
a dielectric structure deposited over the first electrode, the dielectric structure having an overall capacitance density of greater than 25 nF/mm², including:
a current leakage inhibiting layer having a thickness of between 15 Å and 45 Å, and
a substantial amount of Nb₂O₅ in combination with the current leakage inhibiting layer; and
a second electrode deposited over the dielectric structure.

2. A miniature capacitor in accordance with claim 1 wherein the dielectric structure is a multilayer structure and the current leakage inhibiting layer includes a layer of Al₂O₃ at least 22 Å thick.

3. A miniature capacitor in accordance with claim 1 wherein the dielectric structure is a multilayer structure and the current leakage inhibiting layer includes a layer of HfO₂ at least 22 Å thick.

4. A miniature capacitor in accordance with claim 1 wherein the dielectric structure is a multilayer structure and the current leakage inhibiting layer includes a layer of ZrO₂ at least 22 Å thick.

5. A miniature capacitor in accordance with claim 1 wherein the dielectric structure is a multilayer structure and the current leakage inhibiting layer includes a layer of SiO₂ at least 22 Å thick.

6. A miniature capacitor in accordance with claim 1 wherein the overall capacitance density is greater than 30 nF/mm² and the dielectric structure further has a leakage current density of less than 1.0×10⁻⁷ amps/cm².

7. A miniature capacitor in accordance with claim 1 wherein the overall capacitance density of greater than 50 nF/mm² and a leakage current density of less than 1.0×10⁻⁵ amps/cm².

8. A miniature capacitor in accordance with claim 1 wherein at least one of the first and second electrodes includes NbN.

9. A miniature capacitor in accordance with claim 1 wherein at least one of the first and second electrodes includes a transition metal nitride material selected from the group consisting essentially of WN, WSiN, TaN, and TiSiN.

10. A miniature capacitor in accordance with claim 1 wherein at least one of the first and second electrodes includes a noble metal or noble metal alloy material selected from the group consisting essentially of Pt, Pt alloy, Ir, Ir alloy, Pd, Pd alloy, RuOₓ, and IrOₓ.

11. A miniature capacitor in accordance with claim 1 wherein the dielectric structure is formed by ALD.

11. A miniature capacitor in accordance with claim 1 wherein at least one of the first and second electrodes is formed by ALD.

12. A miniature capacitor in accordance with claim 1 wherein the dielectric structure and at least one of the first and second electrodes is formed in an ALD reaction chamber in a single processing cycle.

13. A miniature capacitor in accordance with claim 1 wherein the dielectric structure is a multilayer structure and the current leakage inhibiting layer includes at least two separate layers of a current leakage inhibiting material and at least one layer of Nb₂O₅ material interposed between the layers of the current leakage inhibiting material.

14. A DRAM device including a miniature capacitor in accordance with claim 1.

15. A method of forming a dielectric structure on a substrate, comprising:
depositing a current leakage inhibiting material over the substrate until the current leakage inhibiting material is between 15 Å and 45 Å thick; and
depositing a substantial amount of Nb₂O₅ over the substrate in combination with the current leakage inhibiting material, wherein the resulting dielectric structure has an overall thickness of at least approximately 49 Å and an overall capacitance density of greater than 25 nF/mm².

16. A method in accordance with claim 15 wherein:
the depositing of the current leakage inhibiting material includes depositing a layer of Al₂O₃; and
the depositing of the Nb₂O₅ includes depositing a layer including a substantial amount of Nb₂O₅ overlying the layer of Al₂O₃.

17. A method in accordance with claim 15 further comprising forming a protective cap layer over the current leakage inhibiting material and the Nb₂O₅ via ALD.

18. A method in accordance with claim 15 further comprising forming an electrode over the substrate before depositing the current leakage inhibiting material and the Nb₂O₅.

19. A method in accordance with claim 18 wherein the Nb₂O₅ is deposited against the electrode and the electrode includes NbN.

20. A method in accordance with claim 18 wherein Nb₂O₅ is deposited against the electrode and the electrode includes a transition metal nitride material selected from the group consisting of WN, WSiN, TaN, and TiSiN.

21. A method in accordance with claim 18 wherein Nb₂O₅ is deposited against the electrode and the electrode includes a noble metal or noble metal alloy material selected from the group consisting essentially of Pt, Pt alloy, Ir, Ir alloy, Pd, Pd alloy, RuOₓ, and IrOₓ.

22. A method in accordance with claim 15 wherein the depositing of the current leakage inhibiting material and the Nb₂O₅ includes forming a multi-layer structure having two or more layers of current leakage inhibiting material and one or more layers of Nb₂O₅.

23. A method in accordance with claim 15 wherein ALD is used to deposit the current leakage inhibiting material and the Nb₂O₅.

24. A miniature capacitor including a dielectric structure formed in accordance with the method of claim 15.

25. A DRAM device including miniature capacitors having dielectric structures formed in accordance with the method of claim 15.

26. A niobium containing dielectric structure formed by ALD and characterized by a capacitance density of greater than 30 nF/mm² and a leakage current density of less than 1.0×10₋₇ amps/cm².

27. A miniature capacitor including a niobium containing dielectric structure in accordance with claim 26.

28. A DRAM device including a miniature capacitor in accordance with claim 27.

29. A niobium containing dielectric structure formed by ALD and characterized by a capacitance density of greater than 50 nF/mm² and a leakage current density of less than 1.0×10⁻⁵ amps/cm².

30. A miniature capacitor including a niobium containing dielectric structure in accordance with claim 29.

31. A DRAM device including a miniature capacitor in accordance with claim 30.
